(19) United States
(12) Patent Application Publication
(10) Pub. No.: US 2012/0205744 A1
(43) Pub. Date: Aug. 16, 2012

(54) BODY CONTACT STRUCTURE FOR A SEMICONDUCTOR DEVICE

(76) Inventors: Kenneth K. O, Plano, TX (US); Chieh-Lin Wu, Dallas, TX (US)

(21) Appl. No.: 13/370,395

(22) Filed: Feb. 10, 2012

Related U.S. Application Data
(60) Provisional application No. 61/441,530, filed on Feb. 10, 2011.

(51) Int. Cl. H01L 29/78; H01L 21/336; H01L 21/265

(52) U.S. Cl. 257/352; 438/514; 438/151; 257/E29.255; 257/E21.334; 257/E21.409

(57) ABSTRACT

Embodiments of the invention provide SOI body-contacted transistors that can be used for high frequency analog and digital circuits. In accordance with certain embodiments of the invention, the SOI transistor gate can have an “I” shape, similar to the shape of the gate of a floating body SOI transistor. However, a body region is provided that extends perpendicular to the width direction of the gate and is contacted at an end of the extended body region. To form such a body contact structure, a source/drain implant block mask and silicide block mask are used during the formation of the source/drain regions. The source/drain implant block mask and silicide block mask can be formed on the same region, but the silicide block mask can allow for the body contact portion at the end of the extended body region to be silicided during the siliciding of the source/drain regions.

### CROSS-REFERENCE TO RELATED APPLICATION

The present application claims the benefit of U.S. Provisional Application Ser. No. 61/441,530, filed Feb. 10, 2011, which is hereby incorporated by reference herein in its entirety, including any figures, tables, or drawings.

This invention was made with government support under Contract No. FA8650-09-C-7924 awarded by the Air Force Research Laboratory (AFRL). The government has certain rights in the invention.

### BACKGROUND OF THE INVENTION

As devices continue to be miniaturized, silicon-on-insulator (SOI) technology continues to be of interest to device manufacturers due to SOI having better isolation to the substrate as compared to bulk silicon technologies. Hence, some effects, such as substrate coupling and latch-up, can be mitigated or eliminated by using SOI technology. SOI transistor devices implemented for digital integrated circuits tend to be floating body-type, where the transistor's body is not connected to a specific potential source. However, the floating body of an SOI transistor device allows the threshold voltage of the device to change with the particular switching history that the device experienced in operation (also referred to as the kink effect). In addition, the floating body effects can reduce output resistance and result in a lower breakdown voltage.

Therefore, to address the effects of the floating body (FB) SOI transistor, a contact to the body is built and connected to a specific potential source. This structure is referred to as a body-tied (BT) transistor and is used for analog applications. Although the BT transistor structure is currently one of the preferred structures for RF/millimeter wave applications, the layout of the BT transistor can limit its use in high frequency analog and RF/millimeter wave circuits.

For example, one common BT transistor structure is shown in FIG. 1, which uses a “T” shaped poly gate to form the body contact. This structure is referred to as a T-gate body contact transistor.

Another BT transistor structure is shown in FIG. 2, which uses an “L” shaped poly gate to form the body contact and is referred to as an L-gate body contact transistor.

Both of these structures have lower f_{T} (frequency at which the transistor's current gain falls to unity) and fₘₐₓ (frequency at which the transistor's power gain falls to unity) as compared to that of FB SOI transistors due to the additional parasitic capacitance from the gate polysilicon extension, limiting their use in high frequency analog and RF/millimeter wave circuits.

### BRIEF SUMMARY

Embodiments of the invention provide device structures that can be used for analog circuits (including those operating at RF and microwave frequencies) and RF/millimeter wave digital or mixed signal circuits.

According to certain embodiments, structures for semiconductor devices formed on a SOI substrate are provided that enable access to a semiconductor region covered by part of the device structure. In a further embodiment, access is enabled while also reducing parasitic capacitance effects found in related art approaches. In a specific embodiment, a metal oxide semiconductor field effect transistor (MOSFET) with a body contact is provided.

According to one aspect of the invention, an SOI transistor is provided with a body contact structure that can be fabricated in a standard SOI technology without additional processing steps.

According to another aspect of the invention, a BT SOI transistor is provided that has lower parasitic capacitance between gate and body as compared to existing BT SOI transistor structures.

According to yet another aspect of the invention, a body contact structure of an SOI transistor is formed without bending the original poly gate structure as in the case of the T-gate and L-gate body contact SOI transistors, which enables reduction in the wiring complexity of the gate connection to other devices on a same chip.

According to an embodiment of the invention, a BT SOI transistor is provided having a structure in which the body region extends perpendicular to the width direction of the gate. In accordance with embodiments of the invention, the gate of the transistor can have an “I” shape, similar to the shape of the gate of a FB SOI transistor.

In one embodiment of the invention, a method of forming a BT SOI transistor is provided that uses a source/drain implant block mask and silicide block mask to make the body region under the poly gate extend in the direction perpendicular to the width of the poly gate. In accordance with certain embodiments of the invention, the source/drain implant block mask is used to achieve a same doping concentration in the extended body as that in the body under beneath poly gate. That is, the body region extending from the channel region can be formed during the source/drain implant step (by being protected by the source/drain implant block mask) and the body contacts can be silicided during the siliciding of the source and drain region.

In accordance with certain embodiments of the invention, the silicide blocking and source/drain implant blocking of the subject SOI transistor allows the body contact to be formed without bending the gate (e.g., having polysilicon of a gate routing in multiple directions).

### BRIEF DESCRIPTION OF THE DRAWINGS

FIG. 1 shows plan view of a layout of a T-gate body contact SOI transistor.

FIG. 2 shows a plan view of a layout of an L-gate body contact SOI transistor.

FIGS. 3A-3D show views of a layout of an I-gate body contact SOI transistor in accordance with certain embodiments of the invention. FIG. 3A shows a plan view of the I-gate body contact SOI transistor; FIG. 3B shows a cross-sectional view of the I-gate body contact SOI transistor of FIG. 3A along line 3B-3B; FIG. 3C shows a cross-sectional view of the I-gate body contact SOI transistor of FIG. 3A along line 3C-3C; and FIG. 3D shows a cross-sectional view of the I-gate body contact SOI transistor of FIG. 3A along line 3D-3D.

FIG. 4 shows a plan view of a layout illustrating an extension of the I-gate body contact having a plurality of gate fingers in accordance with an embodiment of the invention.

FIGS. 5A and 5B show plan views of a basic layout of a FB NFET (FIG. 5A) and a T-gate BT NFET (FIG. 5B) for the example comparison.

FIG. 6 shows a plot of I_{d}-V_{ds} characteristics comparing a T-gate BT NFET, an I-gate BT NFET in accordance with an embodiment of the invention, and a FB NFET.

FIG. 7 shows a plot of output conductance g_{ds} comparing a T-gate BT NFET, an I-gate BT NFET in accordance with an embodiment of the invention, and a FB NFET, for V_{gs}=0.6V.

FIG. 8 shows a plot of C_{gg} comparing a T-gate BT NFET, an I-gate BT NFET in accordance with an embodiment of the invention, and a FB NFET, for V_{ds}=0.1V and V_{gs}=1V.

FIG. 9 shows a plot of gₘ comparing a T-gate BT NFET, an I-gate BT NFET in accordance with an embodiment of the invention, and a FB NFET, for V_{ds}=1V and V_{gs}=0.6V.

FIG. 10 shows a plot of f_{T} vs V_{gs} comparing a T-gate BT NFET, an I-gate BT NFET in accordance with an embodiment of the invention, and a FB NFET, for V_{ds}=1V.

FIG. 11 shows a plot of fₘₐₓ vs V_{gs} comparing a T-gate BT NFET, an I-gate BT NFET in accordance with an embodiment of the invention, and a FB NFET for V_{ds}=1V.

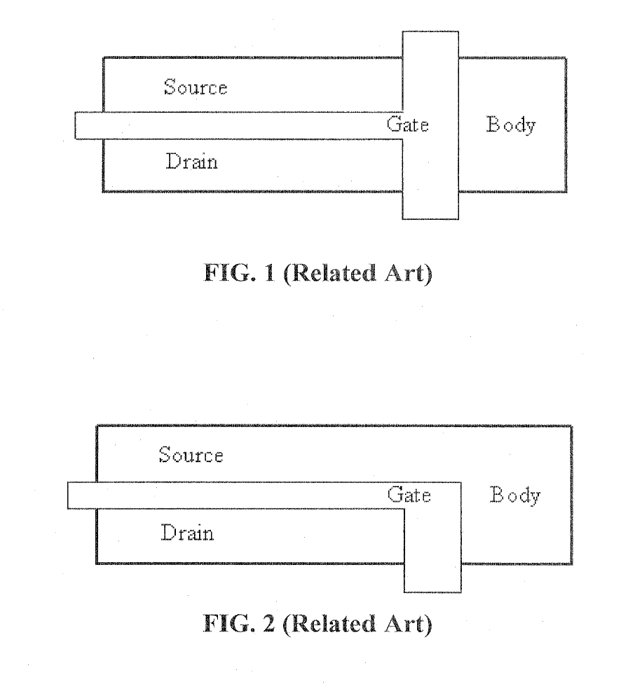

### DETAILED DISCLOSURE

Embodiments of the invention provide a semiconductor region contact structure for a SOI transistor or other device and method of fabricating the same. According to certain embodiments of the invention, a device structure and fabrication method is provided which can facilitate implementation of scalable high frequency digital and analog circuits.

According to an embodiment of the invention, access to a semiconductor region covered by part of the device structure can be accomplished with a reduced parasitic capacitance. In one such embodiment, a first semiconducting region that is denied access from below by an isolation layer and denied access from directly above by an isolation layer and a conductive structure covering the first semiconducting region can be accessed via a first extending portion in the semiconductor substrate that extends at an angle from a side of the first semiconducting region that is also bordered by a second semiconducting region. The first extending portion can be formed at the side of the first semiconducting region during formation of the second semiconducting region by using an implant block mask.

In certain embodiments, the conductive structure can be a gate of a SOI transistor, the first semiconducting region can be the body under the gate, and the second semiconducting region can be a source/drain region in the substrate at a side of the gate.

In accordance with certain embodiments of the invention, the SOI transistor gate can have an “I” shape, similar to the shape of the gate of a FB SOI transistor. For the subject body contact structure, a body region is provided that extends in a direction at an angle to the width direction of the gate. The direction at the angle to the width direction of the gate can be the direction perpendicular to the width direction of the gate. In one embodiment, a body contact can be disposed at two ends of the body region, where one end of the body region is at one side of the gate and the other end of the body region is at an opposite side of the gate. In another embodiment, a body contact is disposed at one end of the body region. By fabricating the subject SOI transistor in accordance with an embodiment of the invention, a same doping concentration can be provided in the extended body as that in the body region under the gate.

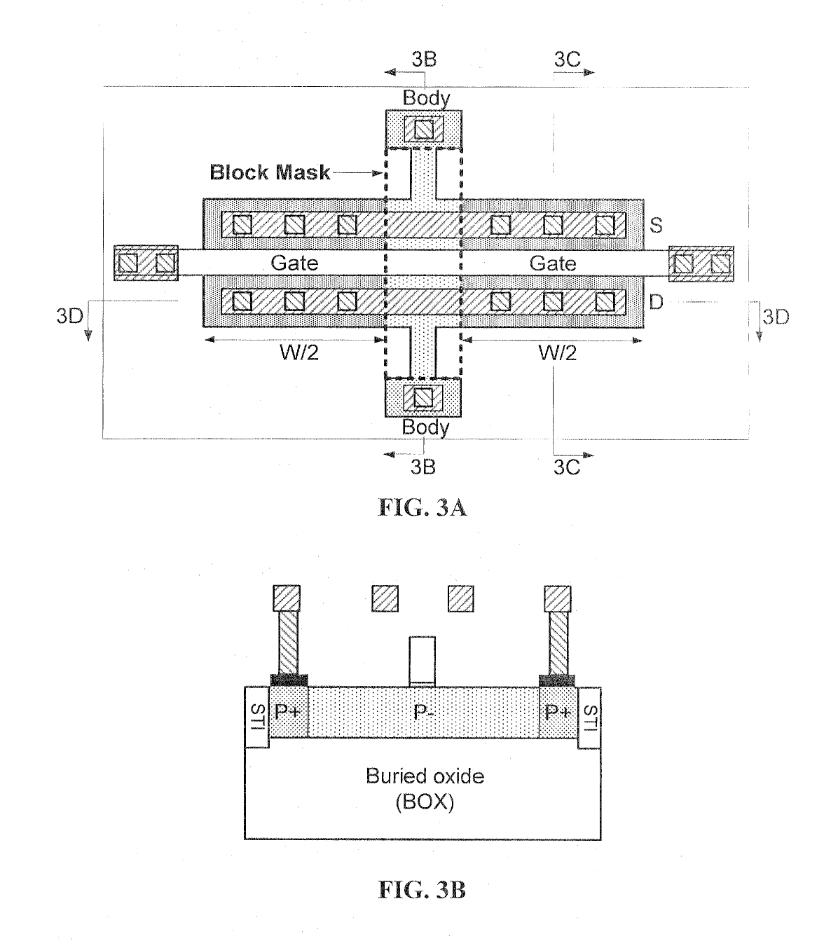

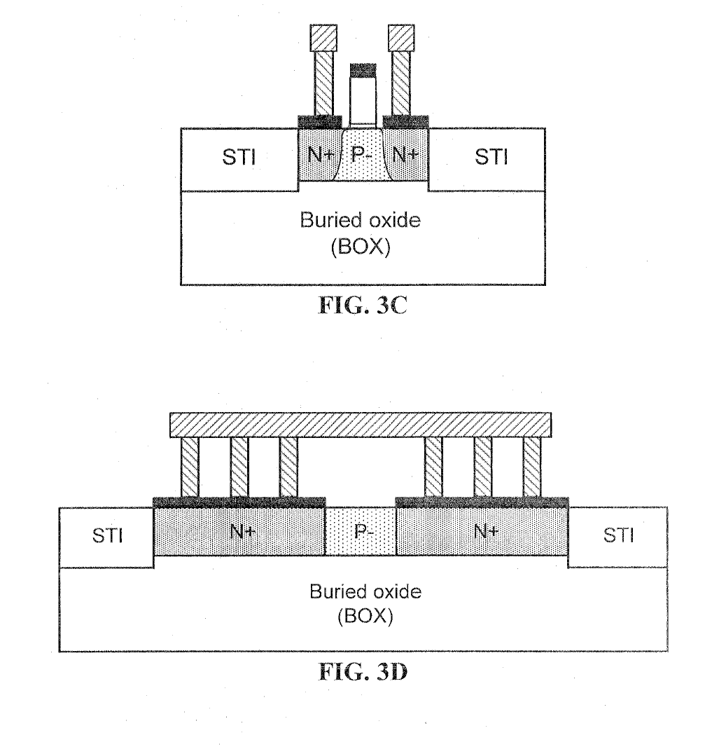

In one embodiment of the invention, a method of forming a BT SOI transistor is provided that uses a source/drain implant block mask and silicide block mask to make the body region under the poly gate extend in the direction perpendicular to the width of the poly gate. The source/drain implant block mask and silicide block mask can be formed on the same region. In an embodiment, such as shown in FIG. 3A, the block masks can be centrally located with respect to the gate width, but embodiments are not limited thereto.

Referring to FIG. 3A, an SOI body contacted FET device structure in accordance with an embodiment of the invention is formed with a straight polysilicon (poly) line labeled Gate. A gate contact region (expanded portion of the polysilicon line sized according to design rule constraints), gate contacts, and metal lines can be formed to connect the Gate to other devices, circuits, and/or power or ground lines. Source S and drain D regions are formed at sides of the poly gate and can include one or more contacts to a metal line for connecting the source and/or drain to other devices, circuits, and/or power or ground lines.

At the center part of the SOI FET, a source/drain implant block mask is used and extended in the direction perpendicular to the width of the poly gate when forming the source and drain. Therefore, the body under the poly gate can be extended perpendicularly to the poly gate width, and its doping condition can be kept uniform without being changed by the source/drain implant. In addition, the silicide block mask can be provided in the same central area covered by the source/drain implant block mask so that the extended body will not be short-circuited with the source or drain through the conductive silicide. At opposing sides (end portions) of the extended body, body contacts can be provided.

For an N-channel device, such as an n-type field effect transistor (NFET), N+ doping can be performed for the drain D and source S regions. In addition, the device layer of the SOI substrate can be P− type such that a body region under the straight polysilicon line is P−. Of course, P+ doping can be performed for forming a p-type field effect transistor (PFET) and the device layer of the substrate can be N− type (or have N-type regions or wells) such that the body region for the PFET is N−.

FIGS. 3B, 3C, and 3D are the cross-sectional views taken along respective lines 3B-3B, 3C-3C, and 3D-3D in FIG. 3A for an NFET device in accordance with an embodiment of the invention. For convenience, dielectric layers and substrate semiconductor base layer of the SOI substrate are not illustrated in the drawings. Although an N-channel device is illustrated in FIGS. 3B-3D, it is readily appreciated that similar doping levels, but reversed polarities, can be used for a p-channel device (e.g., a p-type field effect transistor (PFET)).

Referring to FIG. 3B, the end portions of the extended body can be doped with P+ to form an ohmic body contact. That is, the body contact region can have a high concentration of dopants of the opposite polarity as that of the source and drain. For example, when forming the body contact region, ions can be implanted of the same conductive-type as the body in order to increase the dopant concentration of the body at the body contact region, thereby reducing body contact resistance. In one embodiment, the body contact region for an NFET can be implanted during a source/drain implant of a PFET and vice versa by using suitable implant block masks.

By using the source/drain implant block mask, the body region can have a same doping concentration in the extended body as that in the body under the poly gate. That is, the body region extending from the channel region can be formed during the source/drain implant step by being protected by the source/drain implant block mask. Accordingly, the P− body extends outward from both sides of the channel region below the gate in a line perpendicular to the width direction of the gate. Although not shown in FIG. 3A, the body contact region is also covered by the source/drain implant block mask to protect the ohmic body contact portion from being doped n-type during the source/drain implant step.

The shape of the extended body region can be configured according to minimum design rule constraints and fabricated as an active region bound by, for example, a shallow trench isolation (STI). The STI can extend to the buried oxide of the SOI substrate.

The ohmic body contact region can be silicided during the siliciding of the source and drain regions by exposing the ohmic body contact region while the extended body region is protected by the silicide block mask. One or more contacts can be formed to connect the body contact region to a metal line routing to a particular (voltage) potential. For the embodiment shown in FIG. 3B, the routing lines for the body contact and the routing lines for the source and drain are formed in a same metal layer. However, embodiments are not limited thereto.

The silicide block mask can cover the Block Mask region indicated in FIG. 3A, which exposes the body contact region and the source and drains. By using a silicide block mask covering the extended body while exposing the body contact region, the body contacts can be silicided during the siliciding of the source and drain region. As shown in FIG. 3C, the gate can also be silicided during the siliciding of the source and drain region. When the gate is silicided separately from the source and drain regions, the gate portion over the body region may be silicided. When the gate is silicided simultaneously with the source and drain regions (and the body contacts), the silicide block mask inhibits the gate portion over the body region from being silicided as shown in FIG. 3B. Of course, siliciding process steps can be omitted for certain implementations.

According to certain embodiments, lightly doped drain regions, halo implants, and other channel adjusting or threshold adjusting implants can be provided for the SOI transistor device. In addition, one or more spacers can be formed at sides of the gate.

Referring to FIG. 3D, the body region extending perpendicularly from the channel region under the gate is protected and remains P− type by the source/drain implant block mask during the formation of the source and drain. In addition, one or more contacts can be formed on the drain region to connect to a common metal line for connecting the split drain regions. Similarly, one or more contacts can be formed on the source region to connect to a common metal line for connecting the split source regions. Because of the body region intersecting the gate of the subject SOI transistor, the transistor width can be treated as being the length of the drain (or source) at one side of the body region plus the length of the drain (or source) at the other side of the body region. When the body region is centrally disposed, each side contributes W/2 (as shown in FIG. 3A).

The SOI substrate can be formed via any suitable method for manufacturing the SOI substrate and can be a fully depleted or partially depleted SOI substrate. For example, the SOI substrate can be formed using a layer transfer process, bonding process, or separation by implanted oxygen (SIMOX). In certain embodiments, the SOI substrate is formed via one of the suitable manufacturing processes using a silicon wafer. In another embodiment, the SOI substrate can be a silicon-on-sapphire (SOS) substrate.

Device isolation regions can be formed to isolate adjacent devices and/or circuit regions. When fabricating the subject I-gate body contact transistors, a gate dielectric and gate conductor can be deposited and then patterned to form the I-gate either simultaneously with other gate structures on the SOI wafer or as a separate step. The materials for the gate dielectric can be any suitable dielectric material known in the art. Similarly, various implanting steps can be carried out simultaneously with other regions having different structures or as separate steps.

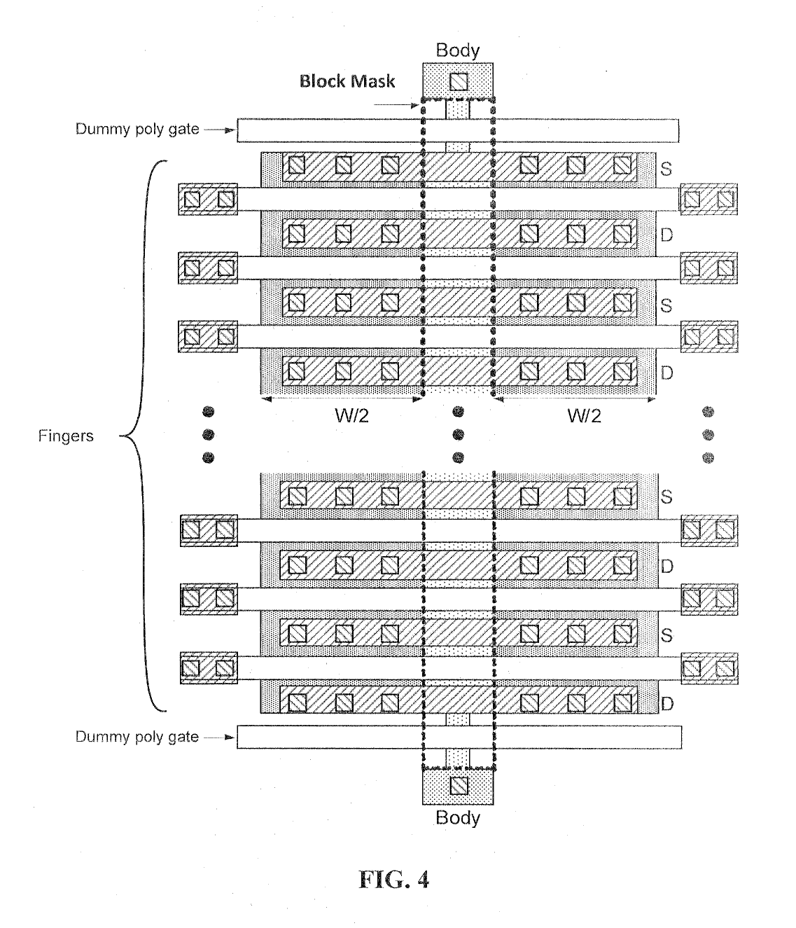

FIG. 4 shows a plan view of a layout illustrating an extension of the I-gate body contact having a plurality of gate fingers in accordance with an embodiment of the invention. As shown in FIG. 4, the extended body portions extend in the direction perpendicular to the gate from an outer side of a first of the plurality of gate fingers through all of the plurality of gate fingers to an outer side of a last of the plurality of gate fingers. Similarly to FIG. 3A, the block mask shown in FIG. 4 would also cover the body contact regions for the source/drain implant block mask, while exposing the body contact regions for the silicide block mask. By forming the block masks in such a manner, the source/drain implant block mask protects the body contacts from being implanted with dopants having the polarity of the source and drain regions and the silicide block mask allows the body contacts to be silicided during siliciding of the source and drain regions.

Even when forming a plurality of gate fingers, two body contacts can be used to (electrically) connect the body across the plurality of gate fingers to a particular potential. This type of layout facilitates minimum spacing for the gate fingers.

In addition, although a dummy poly gate is shown at the outer sides of the plurality of gate fingers in FIG. 4, the particular layout and types of dummy elements can be any suitable dummy patterns for a particular processing layer. For example, dummy poly gates, dummy contacts, dummy active regions, dummy metal contacts, and dummy metal lines can be arranged and configured in any suitable manner known in the art.

Embodiments of the invention can be used as the transistor structure for any circuit fabricated using SOI technology. Embodiments of the invention can also be used to access a covered semiconducting region for devices other than transistors.

In accordance with certain embodiments of the invention, an SOI device having body contact structure is formed on an SOI substrate. By using source/drain implant block and silicide block, a self-aligned SOI FET can have a body contact of low parasitic capacitance between its body and gate. The body contact formed in accordance with certain embodiments of the invention can reduce the body effect and kink effect, hence improving the performance of the device formed on SOI. Moreover, the fabrication steps to form the subject SOI devices can easily be performed in a standard SOI technology without requiring additional processing steps.

A greater understanding of the present invention and of its many advantages may be had from the following examples, given by way of illustration. The following examples are illustrative of some of the methods, applications, embodiments and variants of the present invention. They are, of course, not to be considered in any way limitative of the invention. Numerous changes and modifications can be made with respect to the invention. In addition, it should be understood that although the transistors described herein are in the form of MOSFET transistors, embodiments of the invention are not limited thereto.

### Example

An I-gate BT SOI transistor according to an embodiment of the invention is fabricated, and exhibits comparable f_{T} and fₘₐₓ as that of a FB SOI transistor and comparable analog performance as that of a T-gate BT transistor. For the example embodiment, an I-Gate BT n-type transistor was designed according to the configuration shown in FIGS. 3A-3D.

For the example, embodiment, the n+ doped regions form drain and source, and the body region under the straight polysilicon line is p− doped. At the center of transistor/gate polysilicon, the source/drain implantation is blocked to form a p− region (0.2 μm wide) which is extended in the direction perpendicular to the width of the polysilicon gate. At the ends of extension, p+ body contacts are formed. A silicide block mask is used in the same source/drain implant blocked area (but not covering the body contact region) so that the extended body is not short circuited to a source or a drain through the silicide layer.

The split sources and drains are connected together using metal-1 connections. The I-gate BT transistor includes an additional 0.008 μm² (0.2 μm×0.04 μm) polysilicon gate area to form the p-body contact region, which is ˜2.3 times smaller than the area (0.136 μm×0.136 μm=0.0185 μm²) needed in a T-gate BT transistor fabricated in the same technology node. This primarily results from the length of upper bar of T-gate being larger than the minimum channel length, which is required to keep n implants out of the p-body region.

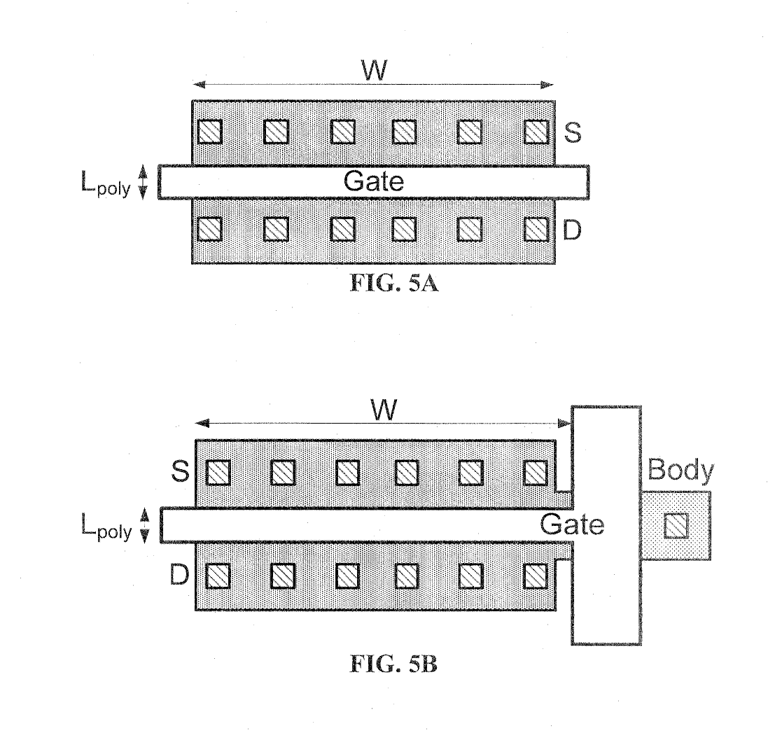

The I-gate BT transistor, a T-gate BT transistor (with basic layout shown in FIG. 5B), and a FB SOI transistor (with basic layout as shown in FIG. 5A) were fabricated in the same chip. All of the three transistors were fabricated in a partially-depleted (PD) SOI technology (where the thickness of the active layer is such that, during transistor operation, the depletion region extends into the body of the transistor under the gate at the source-body and drain-body junctions, but does not deplete all of the charge in the body).

All of the three transistors have gate contacts on both sides of a finger. The FB transistor and I-gate BT transistor are made to have the same gate contact structure (see FIGS. 3A and 4 for gate contact structure). For the T-gate BT transistor, the left-hand side gate contact structure is the same as those in FB and I-gate BT transistors. At the right-hand side, the gate is contacted on the portion of top bar of the T-gate on shallow trench isolation regions.

The three structures each had a 35 μm total width (35 1-μm wide gate fingers with polysilicon gate contacts on two sides) and a 40-nm drawn polysilicon gate length. Because the extended body of the subject I-gate BT transistor is formed at the center of the transistor for the example embodiment, the finger width on each side of the extended body is 0.5 μm. To provide a good comparison, the three structures were made to have the same number of polysilicon gate and source/drain contacts, and the same near-FET wiring. The layout of I-gate test structure that was fabricated adopted the layout shown in FIG. 4. Only two body contacts at the top and bottom are used, which makes the layout ˜20% and 7% larger than that of the FB transistor and the T-gate BT transistor, respectively.

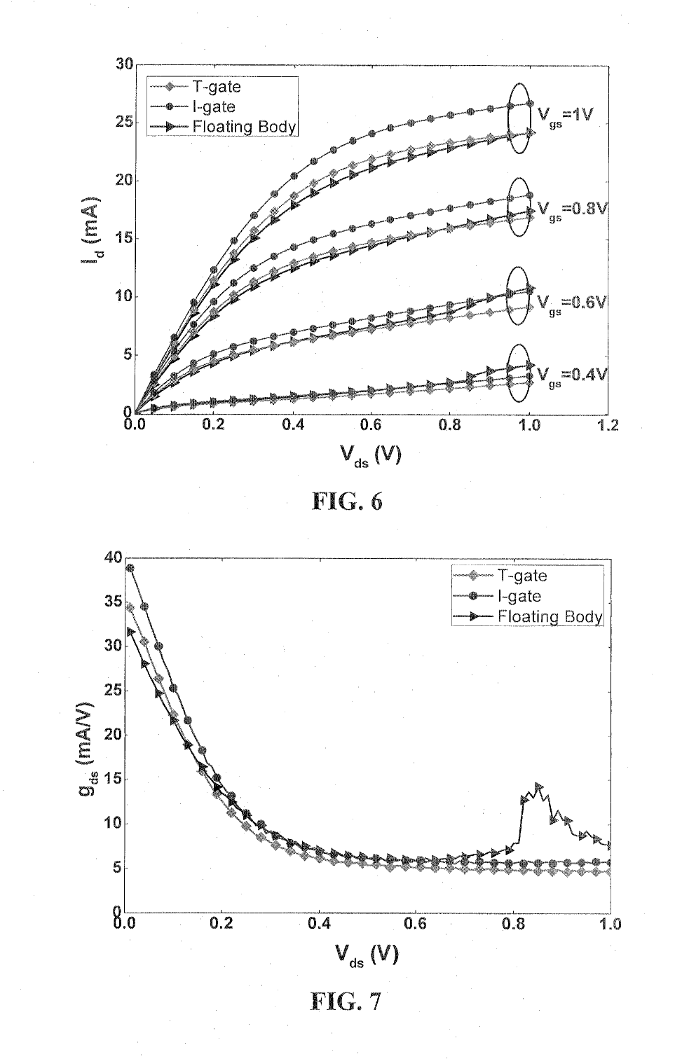

The I_{DS}-V_{DS} characteristics of three types of transistors are shown in FIG. 6. No floating body effect is observed for the I-gate and T-gate BT structures. The drain current of the I-gate BT transistor is higher than that of the other two devices due to slightly larger effective width resulting from the current flow in the channel under the gate in the region without the source/drain implant, and a slightly lower threshold voltage. FIG. 7 compares the output conductance g_{ds} of the three transistors at V_{gs}=0.6V. The g_{ds} plot of the FB transistor shows a bump that lowers the intrinsic gain, which is undesirable for certain analog applications.

In order to investigate the suitability of the subject I-gate BT transistor for high frequency analog and millimeter-wave applications, S-parameters were measured and compared. To evaluate the practical device performance in circuits, the measured AC characteristics are de-embedded to the top metal connections using open and short de-embedding structures. Because of this arrangement, the measured S-parameters include the impact of near-transistor wiring parasitic resistances and capacitances.

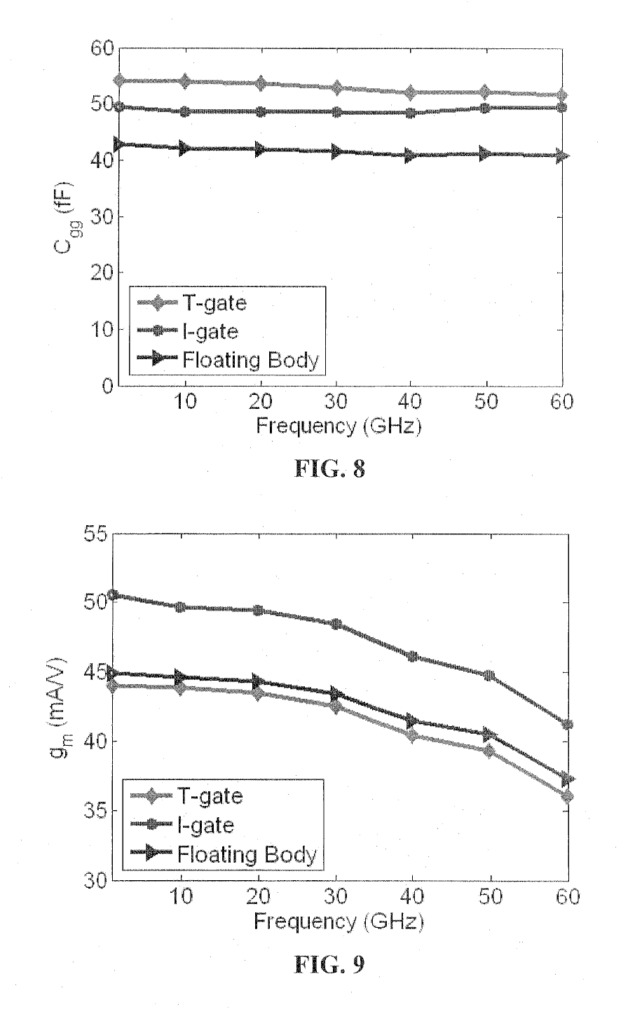

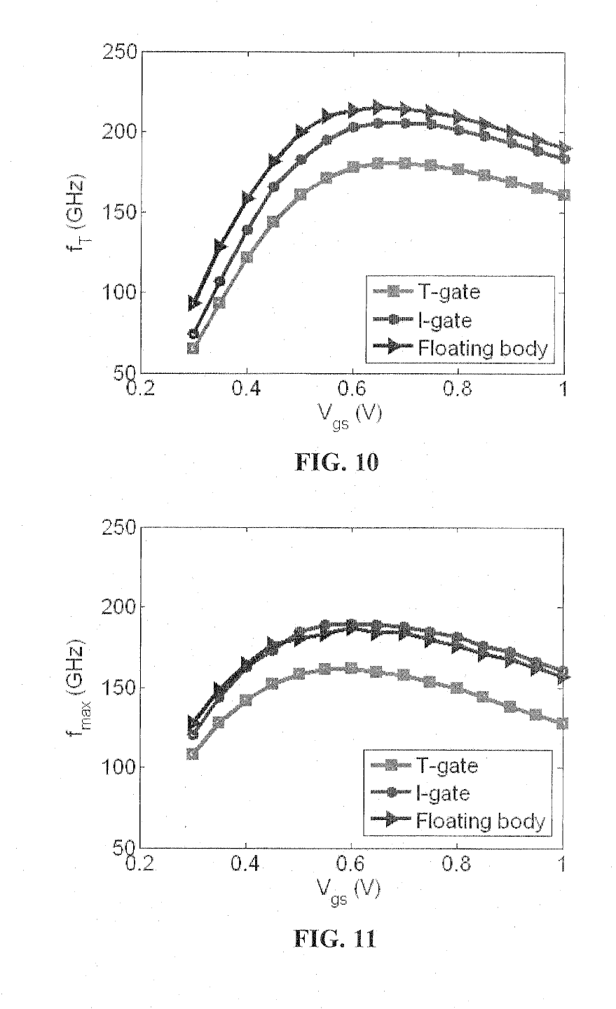

The gate capacitance C_{gg} and the transconductance gₘ of the three transistors are extracted from the measurements. FIG. 8 shows a plot of the gate capacitance measurements and FIG. 9 shows a plot of the transconductance measurements. As shown in the plots, the I-gate BT transistor has ˜9% smaller C_{gg} and ˜13% higher AC transconductance gₘ than that of T-gate BT transistor. FIGS. 10 and 11 show plots of f_{T} and fₘₐₓ, respectively, for different V_{gs}. As shown in FIGS. 10 and 11, the subject I-gate BT transistor has 205 GHz peak f_{T} and 190 GHz peak fₘₐₓ, while the T-gate BT transistor only has 180 GHz f_{T} and 160 GHz peak fₘₐₓ. The peak f_{T} and fₘₐₓ of FB transistors are 215 and 190 GHz. The differences of f_{T} are consistent with the differences of C_{gg} and gₘ.

By using the subject I-gate BT transistor structure, high frequency performance comparable to that of FB transistors, and dc and low frequency analog performance similar to T-gate BT transistors are achieved without any significant process modifications in a floating body SOI technology.

Although the width of the source/drain and silicide blocks were fabricated at 0.2 μm in the example, embodiment, it is possible to further increase the peak fₘₐₓ and f_{T} of I-gate transistors by decreasing the width of source/drain and silicide blocks.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

It should be understood that the examples and embodiments described herein are for illustrative purposes only and that various modifications or changes in light thereof will be suggested to persons skilled in the art and are to be included within the spirit and purview of this application.

What is claimed is:

1. A semiconductor device, comprising:
a first semiconducting region in an active region of a substrate;
a second semiconducting region in the active region of the substrate at a first side of the first semiconducting region;
a first insulating layer on the first semiconducting region;
a conductive structure on the first insulating layer, the conductive structure covering the first semiconducting region;
a contact region in the active region for contacting to the first semiconducting region; and
a contact conductor on the contact region,
wherein the contact region comprises a first extending portion extending at an angle from the first side of the first semiconducting region, and a first contacting region at an end of the first extending portion, wherein the contact conductor is on the first contacting region.

2. The semiconductor device according to claim 1, wherein the active region overlies an insulating layer of the substrate.

3. The semiconductor device according to claim 1, wherein the substrate comprises a silicon-on-insulator (SOI) substrate.

4. The semiconductor device according to claim 1, wherein the substrate comprises a silicon-on-sapphire (SOS) substrate.

5. The semiconductor device according to claim 1, further comprising:
a third semiconducting region in the active region of the substrate at a second side of the first semiconducting region; and
a second contact conductor on the contact region,
wherein the contact region further comprises:
a second extending portion extending at an angle from the second side of the first semiconducting region, and a second contacting region at an end of the second extending portion, wherein the second contact conductor is on the second contacting region

6. The semiconductor device according to claim 1, wherein:
the conductive structure is a gate of a transistor;
the second semiconducting region is a source/drain region of the transistor; and
the contact region is a body contact region, wherein the first extending portion extends in a direction at an angle to a width direction of the gate.

7. The semiconductor device according to claim 6, wherein the contact region further comprises a first ohmic body contact portion at the end of the first extended portion on which the contact conductor is formed.

8. The semiconductor device according to claim 6, further comprising a first conductive body contact on the contact region at the end of the first extended portion upon which the contact conductor is formed, the first conductive body contact being spaced from the side of the gate by a portion of the contact region not having conductive material of the first conductive body contact thereon.

9. The semiconductor device according to claim 8, wherein the first conductive body contact comprises a first silicide body contact, wherein the portion of the contact region not having the conductive material thereon comprises a silicide blocked portion of the contact region.

10. The semiconductor device according to claim 6,
wherein the first extended portion separates the source/drain region into two source/drain regions.

11. The semiconductor device according to claim 10, wherein each of the two source/drain regions have a width of about W/2, where W is a transistor width of the transistor.

12. The semiconductor device according to claim 10, further comprising a first metal line electrically connecting the two source/drain regions via source/drain contacts.

13. The semiconductor device according to claim 6, wherein the direction at the angle to the width direction of the gate is a direction perpendicular to the width direction of the gate.

14. A method of fabricating the semiconductor device of claim 6, the method comprising:
forming a source/drain implant block mask on the gate and over the contact region, the source/drain implant block mask extending in the direction at the angle to the width direction of the gate; and
implanting dopants using the source/drain implant block mask as an implant mask to form a source region and a drain region, wherein the source/drain implant block mask inhibits the dopants from being implanted into the first extended portion and a second extended portion extending at a second side of the first semiconducting portion under the gate in the direction at the angle to the width direction of the gate.

15. A method of fabricating a semiconductor device, comprising:
forming a gate on an active region of a substrate;
forming a source/drain implant block mask on the gate, the source/drain implant block mask extending in a direction at an angle to a width direction of the gate; and
implanting dopants into the active region at sides of the gate to form source and drain regions, wherein the source/drain implant block mask inhibits the dopants from being implanted into the active region such that a body extension portion is formed below portions of the source/drain implant block mask extending in the direction at the angle to the width direction of the gate.

16. The method according to claim 15, wherein during the implanting of the dopants into the active region at the sides of the gate to form the source and drain regions, a first portion of the source region and a first portion of the drain region are formed at one side of the source/drain implant block mask and a second portion of the source region and a second portion of the drain region are formed at an opposite side of the source/drain implant block mask.

17. The method according to claim 16, further comprising:
forming source/drain contacts on the source and drain regions; and
forming a first conductive line connecting the first portion of the source region to the second portion of the source region via the source/drain contacts on the source region and a second conductive line connecting the first portion of the drain region to the second portion of the drain region via the source/drain contacts on the drain region.

18. The method according to claim 15, further comprising:
forming a silicide block mask on the gate, the silicide block mask extending in the direction at the angle to the width direction of the gate, wherein the silicide block mask exposes a body contact region at an end portion of the body extension portion; and
performing a silicide process to simultaneously silicide the body contact region and the first and second source regions and the first and second drain regions at sides of the silicide block mask.

19. A semiconductor device, comprising:
a gate on an active layer overlying an insulating layer in a substrate; and
a body contact region in the active layer, the body contact region comprising:
a first extended body portion extending at a first side of the gate from a portion of the active layer under the gate in a direction at an angle to a width direction of the gate; and
a first body contact at an end of the first extended body portion.

20. The semiconductor device according to claim 19, wherein the body contact region further comprises:
a second extended body portion extending at a second side of the gate from the portion of the active layer under the gate in a direction at an angle to the width direction of the gate; and
a second body contact at an end of the second extended body portion.

21. The semiconductor device according to claim 20, further comprising:
a source region in the active layer at the first side of the gate; and
a drain region in the active layer at the second side of the gate,
wherein the first extended body portion separates the source region into two source regions and the second extended body portion separates the drain region into two drain regions.
